(19) United States
(12) Patent Application Publication
(10) Pub. No.: US 2008/0112162 A1
(43) Pub. Date: May 15, 2008

(54) Backlight Structure Having Embedded LEDs and Fabrication Method Thereof

(75) Inventor: Tsung-Wen Chan, Taipei (TW)

Correspondence Address: PAI PATENT & TRADEMARK LAW FIRM, 1001 FOURTH AVENUE, SUITE 3200, SEATTLE, WA, 98154, US

(73) Assignee: TOPSON OPTOELECTRONICS SEMI-CONDUCTOR CO., LTD., Taoyuan County (TW)

(21) Appl. No.: 11/558,171

(22) Filed: Nov. 9, 2006

(51) Int. Cl. F21V 9/00; H01L 33/00

(52) U.S. Cl. 362/230; 438/27; 257/E33.057

(57) ABSTRACT

The present invention discloses a backlight structure having embedded light emitting diodes (LEDs) and a fabrication method thereof. The backlight structure comprises a PCB having a plurality of arc-shaped pits and necessary circuitry implemented thereon; a nanometer-thick gold layer sputtered on surfaces of said PCB and said plurality of arc-shaped pits; and an LED die embedded in each one of said plurality of arc-shaped pits, wherein said LED die is fused and fixed to the center of said arc-shaped pit by high frequency wave; said LED die is covered with a phosphor molding compound made by mixing phosphor and silica gel; and each one of said plurality of arc-shaped pits and its neighboring portion of PCB is covered by a window layer formed by transparent silica gel.

### BACKGROUND OF THE INVENTION

1. Field of the Invention

The present invention relates to a backlight structure having embedded LEDs and, more particularly, to a structure implemented by forming arc-shaped pits on a PCB and sputtering the whole PCB with a nanometer-thick gold layer to enhance heat and electrical conductivities. The backlight structure disclosed facilitates packaging of LED dice and improves yield rate and quality of LCD backlights.

2. Description of the Prior Art

At present, LCD backlights adopt white light CCFLs (Cold Cathode Fluorescent Lamps) and have CCFLs disposed behind LCD. The light generated by a CCFL is transmitted through a light guiding plate, a diffuser and a brightness enhancement film (BEF), then projected onto a LCD to let the LCD display contents. As the size of LCD grows larger, the number of CCFLs and circuits needed increases as well. In order to provide backlight illumination for a large area, a plurality of CCFLs have to be coupled in series/in parallel. However, problems arise due to inherent properties of CCFLs, such as:

1. CCFL doesn't provide uniform brightness in the area of a LCD even if coupled in series/in parallel. The problem is even worse when the size of LCD increases.

2. CCFL tends to have a short lifetime, and the brightness of CCFL decreases after 4,000 to 6,000 hours of use. Besides, it is difficult to replace CCFL, therefore, LCD has a rather short lifetime.

3. CCFL doesn't provide enough color saturation, and its color temperature is around 4,800K, barely reaching a color gamut of 80% NTSC. In particular, CCFL performs even worse for red light, making it unable to meet high standard requirements of color performance under the measurement of high precision instrument or specific color reproduction.

4. CCFL consumes lots of power and contains mercury in the fabricating process, which causes damage to the environment. Therefore, the Kyoto Protocol has promulgated rules for restricting use of mercury starting Jul. 1, 2006. It is inevitable for LCD industry to adopt other backlight sources other than CCFLs.

5. CCFL generates UV rays, which could harm people's eyes for long term use.

Presently it is common to use light emitting diode (LED) as backlight source, for example, LEDs have been applied in devices using small-size LCDs, such as mobile phones and PDAs. In recent years, as technology gradually improves, the performance of LED has also improved in many aspects, such as brightness, weight rigidness, longer lifetime, shorter turn-on time, therefore, it has become the backlight choice for implementing large-size LCD products.

Generally, LEDs are placed on one or both sides of LCD to act as backlight source. When power is turned on, light emitted from LED is projected onto LCD to display images on LCD. However, LED does not emit light equally in all directions, it tends to focus in a small area, therefore it is brighter in some areas than in other areas under the light of LED and there tends to have obvious brightness degradation around the brightest area. Besides, it is difficult to achieve uniform color reproduction.

For this reason, an alternative way is to place LEDs right behind LCD backlight and to increase the brightness of LEDs to have light uniformly projected on LCD. However, since the brightness of LCD backlight using LED depends on the output power of LEDs, more heat would be generated as the brightness increases. Therefore, it would be difficult for prior art LED-based LCD backlight to efficiently dissipate all the heat generated by LEDs. LEDs, especially white light LEDs, would not be fully operated under this condition. This will cause the lighting efficiency of the whole LCD backlight to decrease and overheating problems to occur every now and then.

Besides, LED dice are soldered onto the PCB in the prior art LCD backlight fabricating method. This not only makes it difficult to process and to increase the yield rate, but also tends to damage the PCB in the soldering process. Moreover, traditional LCD backlight must place a color filter, a diffuser and a light guiding plate between LCD and LED dice for the light guiding plate to guide the light, the diffuser to uniformly distribute the light and the color filter to filter out unwanted color lights. These additional parts raise the manufacturing cost of LCD backlight and affect the development of LCD industry.

Further, when any part of the above-mentioned LCD device is damaged, the whole device has to be replaced. For large-size LCDs, it is not efficient to do so from the perspectives of both cost and environmental conservation.

In view of the above-mentioned deficiencies of prior art LCD backlights, the inventor of the present invention contemplates solving the overheating and brightness degradation problems by a special heat dissipation mechanism, which further simplifies the manufacturing process and enhances the production output. After years of constant efforts in research, the inventor of this invention has consequently developed and proposed a backlight structure having embedded LEDs and a fabricating method thereof.

### SUMMARY OF THE INVENTION

It is an object of the present invention to provide a backlight structure having embedded LEDs and a fabricating method thereof, which uses a special heat dissipation mechanism to greatly reduce chances of failure and to improve the yield rate and the brightness of large-size LCDs.

It is another object of the present invention to provide a backlight structure having embedded LEDs and a fabricating method thereof to provide a simplified structure which is easy to manufacture so as to improve production output and product quality.

It is still another object of the present invention to provide a backlight structure having embedded LEDs and a fabricating method thereof, in which the LCD backlights are built from small modules. In case of failure of a single component, it is viable to replace only the damaged part to make it easy to repair and to maintain.

It is still another object of the present invention to provide a backlight structure having embedded LEDs and a fabricating method thereof, which can simplify the manufacturing process and eliminate the need for soldering and the waste in soldering to meet requirements for environmental conservation.

The present invention discloses a backlight structure having embedded LEDs and a fabricating method thereof. The backlight structure comprises a PCB having a plurality of arc-shaped pits and necessary circuitry implemented thereon; a nanometer-thick gold layer sputtered on surfaces of said PCB and said plurality of arc-shaped pits for providing good electrical and heat conductivity to enable better heat dissipation of said LCD backlight; and an LED die embedded in each one of said plurality of arc-shaped pits, wherein said LED die is fused and fixed to the center of said arc-shaped pit by high frequency wave; said LED die is covered with a phosphor molding compound made by mixing phosphor and silica gel; and each one of said plurality of arc-shaped pits and its neighboring portion of the PCB is covered by a window layer formed of transparent silica gel for protecting the conducting wires inside said arc-shaped pit and for scattering the light emitted from said LED die.

### BRIEF DESCRIPTION OF THE DRAWINGS

The drawings disclose an illustrative embodiment of the present invention which serves to exemplify the various advantages and objects hereof, and are as follows:

FIG. 1 illustrates a perspective view of a backlight structure having embedded LEDs disclosed in the present invention;

FIG. 1A illustrates a partially enlarged view of FIG. 1;

FIG. 2 illustrates a cross-sectional view of the backlight structure having embedded LEDs;

FIG. 3 illustrates the principle of heat dissipation caused by the backlight structure having embedded LEDs;

FIG. 4 shows a flowchart illustrating a manufacturing process of the backlight structure having embedded LEDs;

FIG. 5 illustrates an assembly of the backlight structure having embedded LEDs;

FIG. 6 illustrates another embodiment of the backlight structure having embedded LEDs disclosed in the present invention;

FIG. 7 illustrates an assembly of the backlight structure having embedded LEDs shown in FIG. 6;

FIG. 8 shows a table of temperature variations for a 8-hour period of the present invention embodied in a 32-inch LCD backlight; and

FIG. 8A˜FIG. 8H show temperature variations for a 8-hour period at different positions.

### DETAILED DESCRIPTION OF THE PREFERRED EMBODIMENT

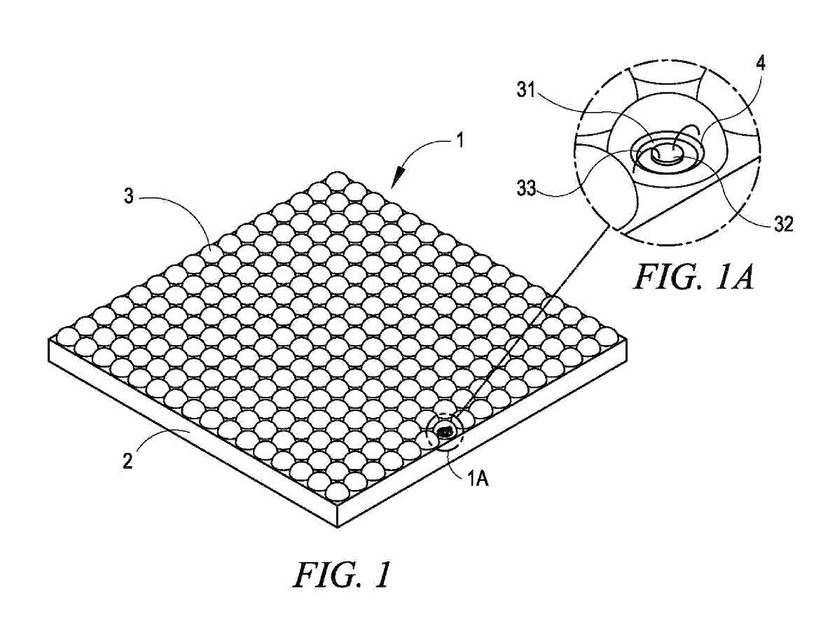

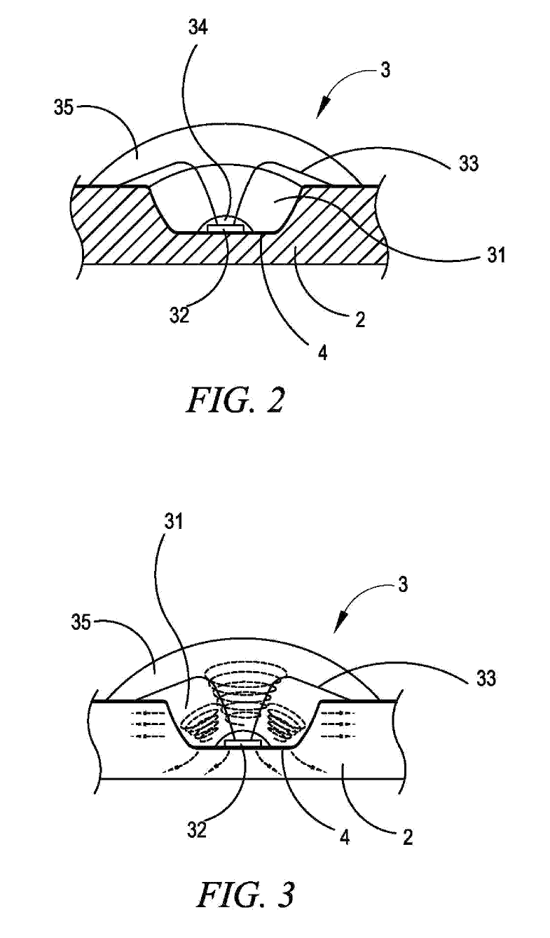

Please refer to FIG. 1, FIG. 1A, and FIG. 2 for a backlight structure having embedded LEDs disclosed in the present invention. The backlight structure has a plurality of LEDs 3 placed on a PCB 2 to form a LCD backlight 1. The LCD backlight 1 is placed behind a LCD (not shown) for emitting light from the plurality of LEDs 3 onto the LCD to obtain the required color hue and brightness.

Each of the above-mentioned LEDs 3 comprises an arc-shaped pit 31 disposed on the PCB 2, which has necessary circuitry implemented thereon for generating backlight; a nanometer-thick gold layer 4 sputtered on surfaces of the PCB 2 and the arc-shaped pit 31 for providing good electrical and heat conductivity to enable better heat dissipation of the PCB 2; and an LED die 32 embedded in the arc-shaped pit 31. Due to the existing nanometer-thick gold layer 4, the LED die 32 is fused and fixed to the nanometer-thick gold layer 4 on the arc-shaped pit 31 a by high frequency wave. The LED die 32 is covered by a phosphor molding compound 34 made by mixing a fixed composition of phosphor (licensed from OSRAM) and silica gel. The high brightness LED 3 so formed can generate a single-wavelength white light having a 8,000K color temperature and a value of X=0.33, Y=0.33 on the chromaticity coordinates. Moreover, the arc-shaped pit 31 and its neighboring portion of the PCB 2 are covered by a window layer 35 formed of transparent silica gel for protecting the arc-shaped pit 31 and the conducting wires 33 inside the arc-shaped pit 31 and for scattering the light emitted from the LED die 32. Hence, the present invention only needs to dispose a diffuser between the LCD and the LCD backlight to generate the needed white light without using color filters and light guide plates disclosed in the prior art structure, thereby greatly simplifying the product's structure.

FIG. 3 illustrates the principle of heat dissipation caused by the above-mentioned backlight structure having embedded LEDs. A portion of the heat generated by the LED die 32 is dissipated through the nanometer-thick gold layer 4 and the PCB 2 on the bottom, while heat flows going up and sideways would generate swirling flows due to heat convection, so that most of the heat flowing through the swirl would likely come in contact with the nanometer-thick gold layer 4 of the arc-shaped pit 31 and be dissipated via the nanometer-thick gold layer 4 and the PCB 2. Consequently, the present invention can provide better heat dissipation than prior art structures.

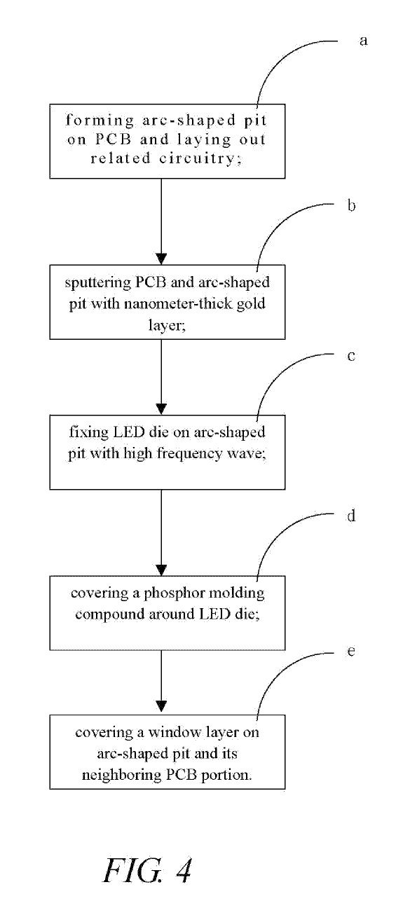

A method of making a backlight structure having embedded LEDs is shown in FIG. 4, comprising:

a. forming a plurality of arc-shaped pits 31 on a PCB 2 and laying out necessary circuitry;

b. sputtering the PCB 2 and the plurality of arc-shaped pits 31 with a nanometer-thick gold layer 4;

c. embedding and fixing a LED die 32 on the nanometer-thick gold layer 4 on each arc-shaped pit 31 with a high frequency wave and laying out conducting wires 33 between each LED die 32 and the PCB 2;

d. covering each LED die 32 with a phosphor molding compound 34; and

e. placing a window layer 35 over each arc-shaped pit 31 and its neighboring portion of the PCB 2.

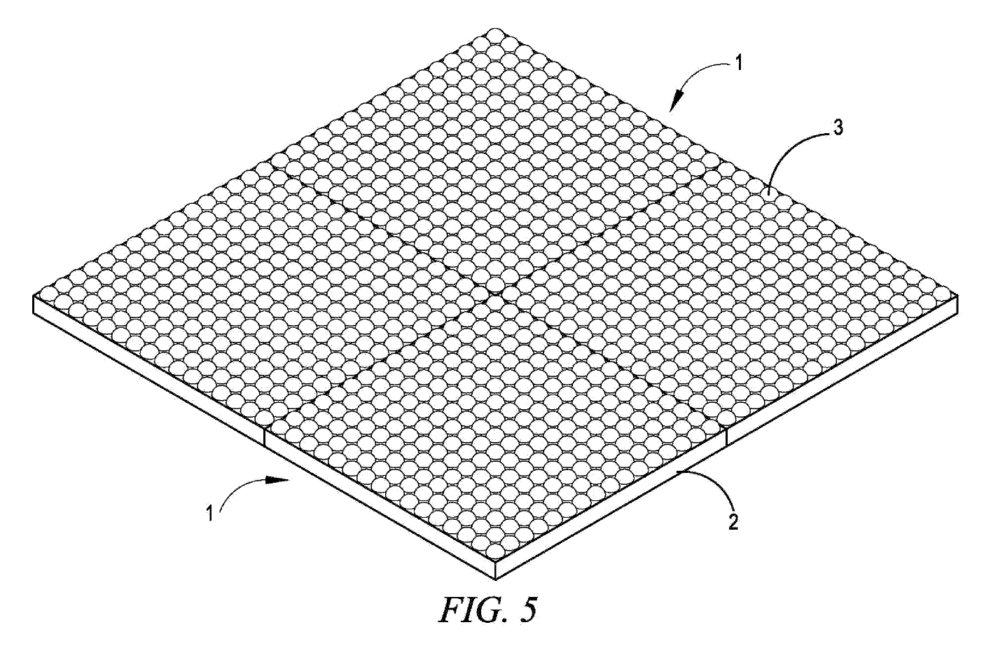

Furthermore, as shown in FIG. 5, the backlight structure comprises several small modules. A plurality of PCB 2 of suitable size can be combined into a small LCD backlight 1, then a plurality of small LCD backlight 1 can be combined into a large LCD backlight 1 according to the required LCD size, thereby enhancing the production output and the yield rate.

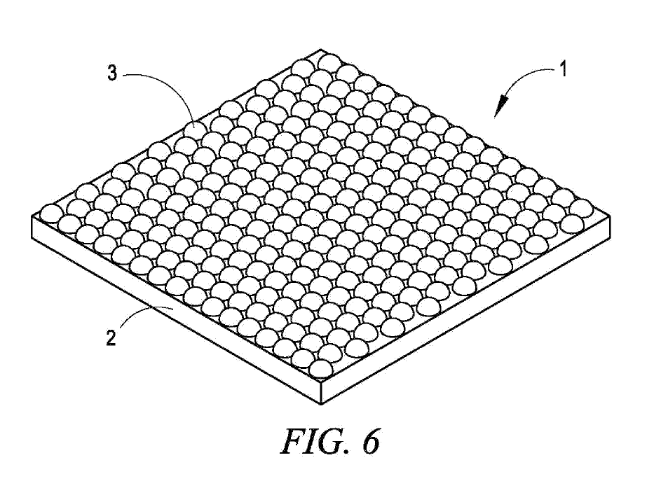

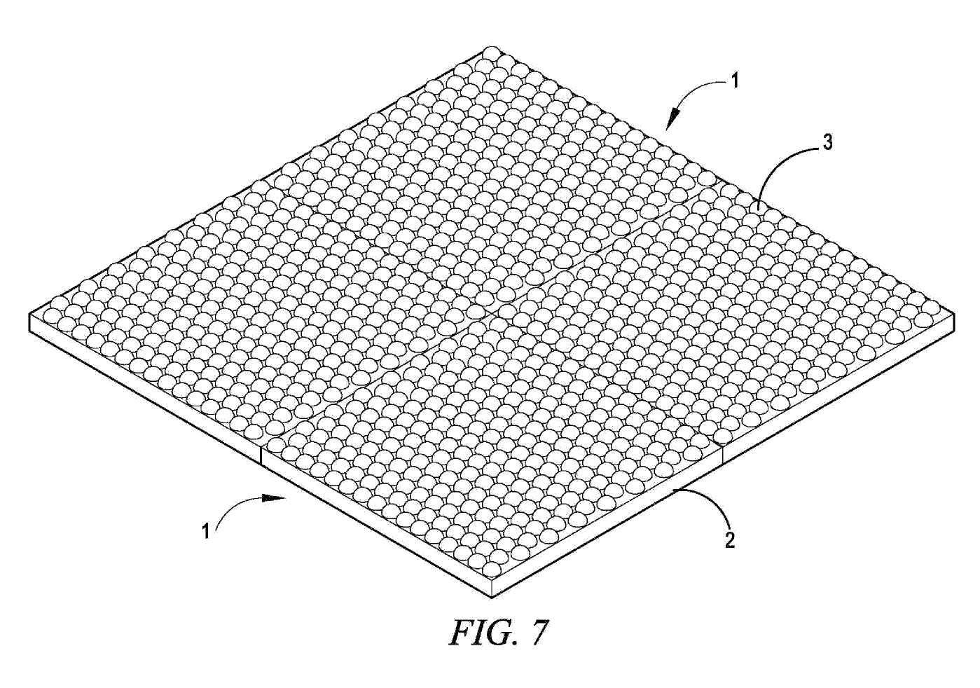

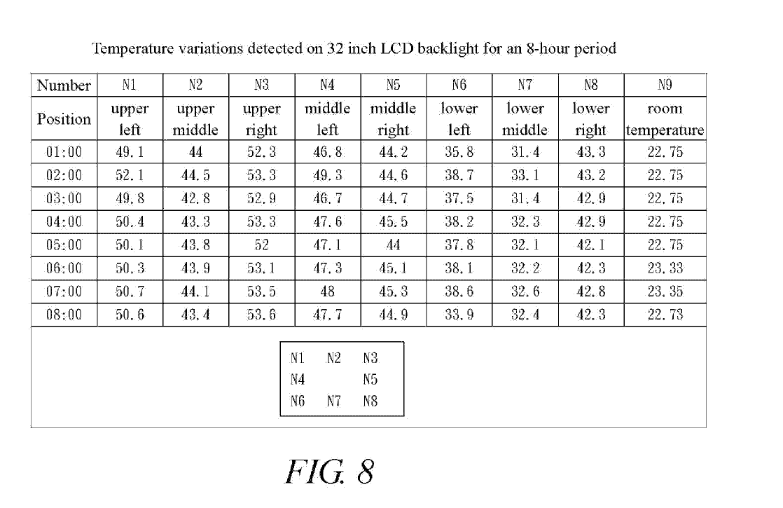

The aforementioned LEDs 3 of LCD backlight 1 are aligned in parallel, however, as shown in FIG. 6 and FIG. 7, LEDs 3 of LCD backlight 1 can be aligned in an interlaced array to provide different visual effect.

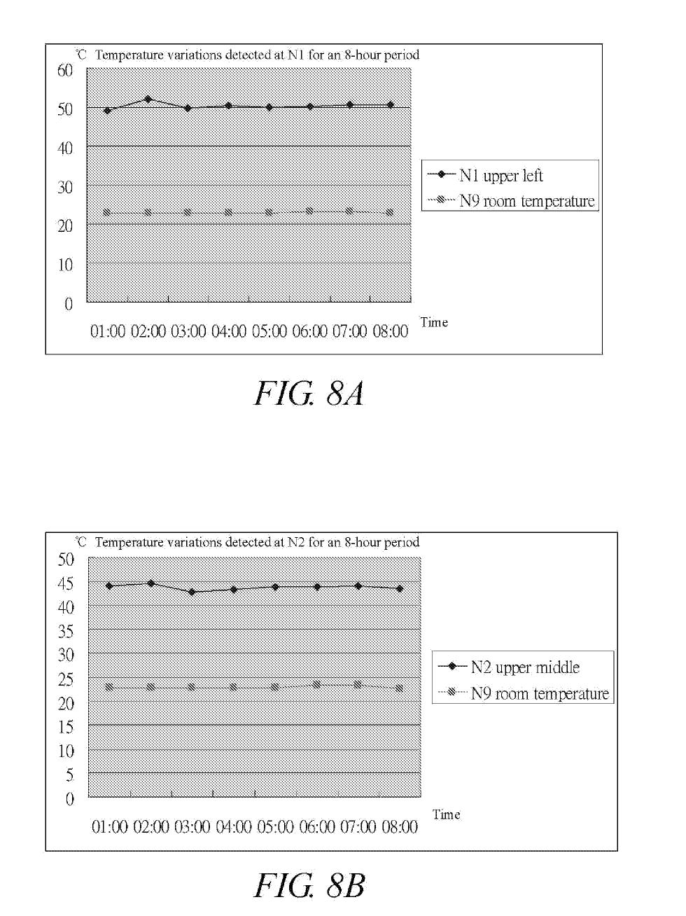

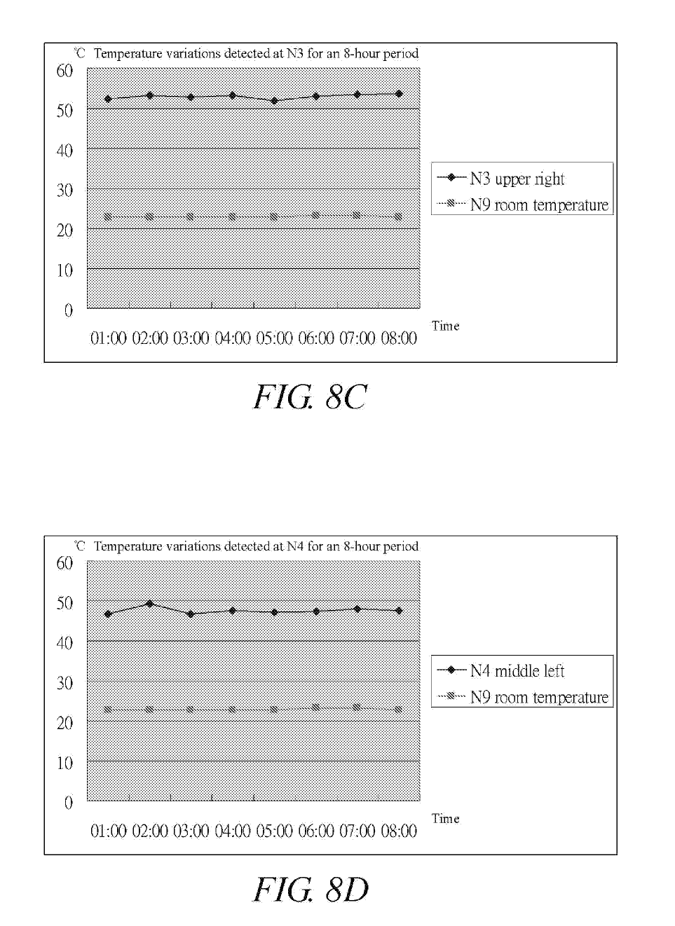

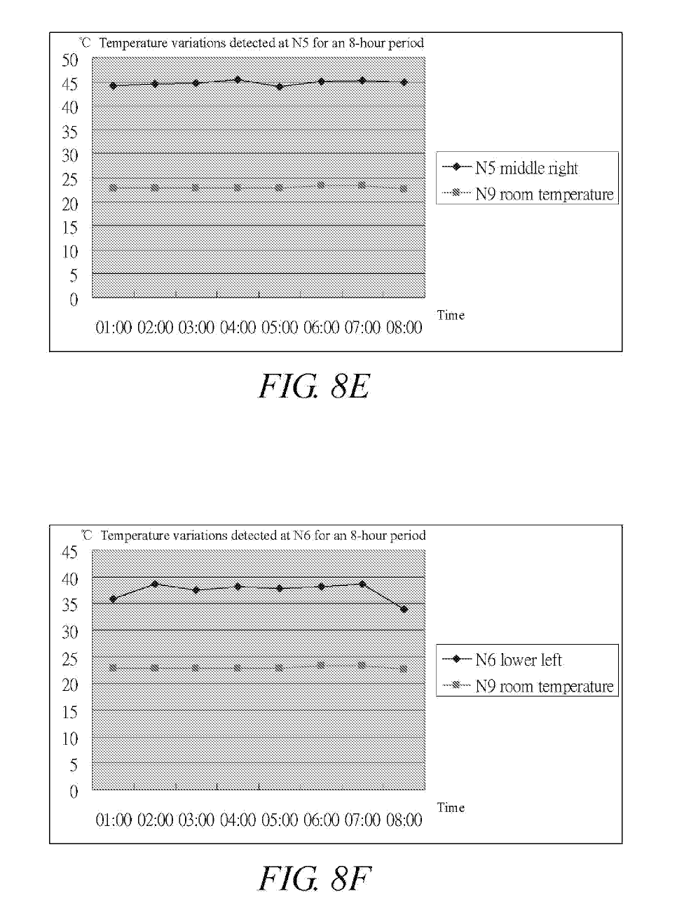

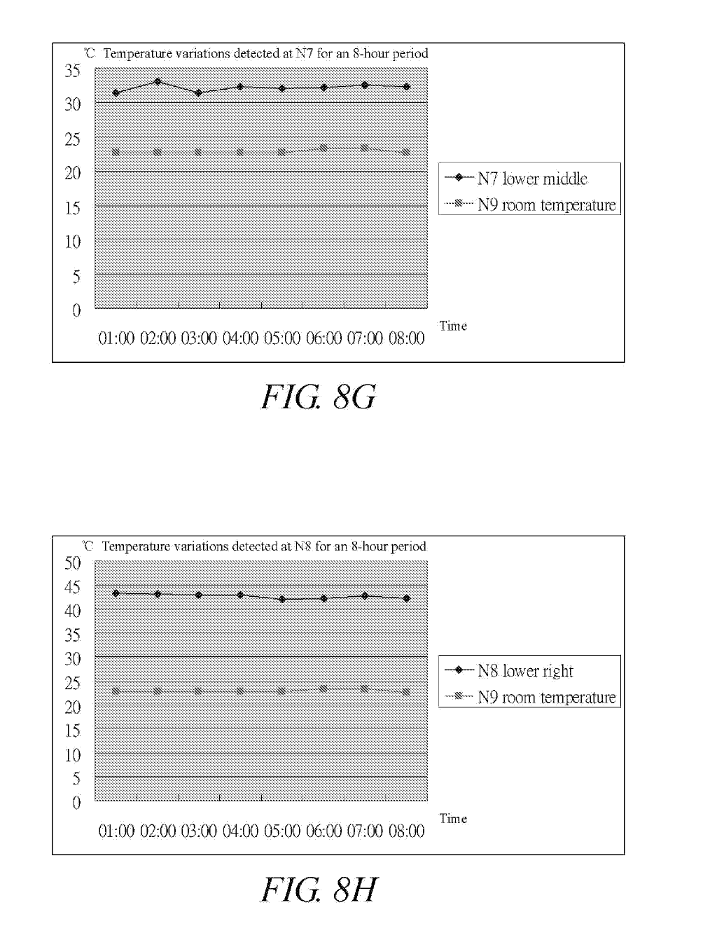

The LCD backlight structure according to the present invention is able to provide high brightness at lower temperature. FIG. 8 through FIG. 8H show the temperature variations on the LCD backlight. In obtaining the data, 8 temperature detecting points (N1˜N8) are placed from left to right, and from top to bottom, on the surface of a 32-inch LCD backlight, with a room temperature detecting point N9 for comparison. In fact, a temperature detecting point on top should be hotter than the temperature detecting point disposed below. For traditional LCD devices, temperature detected at any temperature detecting point would reach or even exceed 100° C., therefore, users are strictly forbidden to open the case of LCD by themselves to prevent electric shock and also to avoid getting burned. However, temperature detected at any position of the LCD backlight structure according to the present invention is no higher than about 50° C., which means the LCD backlight structure according to the present invention could provide high brightness with longer lifetime, making it best for any high brightness applications.

Many changes and modifications in the above described embodiment of the invention can, of course, be carried out without departing from the scope thereof Accordingly, to promote the progress in science and the useful arts, the invention is disclosed and is intended to be limited only by the scope of the appended claims.

What is claimed is:

1. A method of making a backlight structure having embedded light emitting diode (LED), comprising:
forming a plurality of arc-shaped pits on a printed circuit board (PCB) and laying out necessary circuitry;
sputtering said PCB and said plurality of arc-shaped pits with a nanometer-thick gold layer;
embedding an LED die in each of said plurality of arc-shaped pits and laying out conducting wires between the LED die and the PCB;
covering over and around each said LED die with a phosphor molding compound; and
covering a window layer over each said arc-shaped pit and a neighboring portion of the PCB with a window layer.

2. The method of claim 1, wherein said LED die is fixed onto said nanometer-thick gold layer of said arc-shaped pit by high frequency wave.

3. A backlight structure having embedded light emitting diode (LED), comprising:
a printed circuit board (PCB) having necessary circuitry for said backlight implemented thereon;
a plurality of arc-shaped pits formed on said PCB;
a nanometer-thick gold layer sputtered on surfaces of said PCB and said plurality of arc-shaped pits;
a plurality of LED dice, each one of said plurality of LED dice being fixed in a respective one of said plurality of arc-shaped pits and has conducting wires extended to said PCB;
a phosphor molding compound covering over and around each LED die; and
a window layer covering each one of said plurality of arc-shaped pits and its neighboring PCB portion for protection.

4. The backlight structure of claim 3, wherein said phosphor molding compound is made by mixing phosphor and silica gel to let said backlight structure to generate a single-wavelength white light having a 8,000K color temperature and a value of X=0.33, Y=0.33 on the chromaticity coordinates.

5. The backlight structure of claim 3, wherein said window layer comprises transparent silica gel.

6. The backlight structure of claim 3, wherein said backlight structure comprises a small module, and a plurality of small module can be combined into a large LCD backlight.
